(19) United States
(12) Patent Application Publication
(10) Pub. No.: US 2018/0191265 A1
(43) Pub. Date: Jul. 5, 2018

(54) PHOTO-ELECTRIC SWITCH SYSTEM AND METHOD

(71) Applicant: John Bennett, Sammamish, WA (US)

(72) Inventor: John Bennett, Sammamish, WA (US)

(21) Appl. No.: 15/395,442

(22) Filed: Dec. 30, 2016

(51) Int. Cl. H02M 7/00; H03K 17/94

(52) U.S. Cl. CPC H02M 7/006; H03K 17/941

(57) ABSTRACT

A device for the switching of electrical current comprising a photo-cathode, an anode, one or more light sources positioned to illuminate the photo-cathode to stimulate the emission of electrons from the photo-cathode, an electrical circuit connected to and supplying a voltage across the photo-electric cathode and the anode, and a vacuum chamber enclosing at least the photo-cathode and the anode in a vacuum and holding the photo-cathode and the anode in position such that a gap exists between them.

### BACKGROUND

The demand for power continues to increase as more of the planet is modernized and as our population grows. There is a corresponding increase in demand for power from renewable energy sources. Along with the demand for more power is an increasing need to transmit that power over long distances, as power generation facilities continue to be built farther from the load centers they must supply.

Traditionally, the transmission of high voltage has been performed over alternating current (AC) transmission lines. Although the first transmissions systems developed by Thomas Edison were direct current (DC) systems, the systems could not transmit power more than a kilometer or two without suffering significant voltage drops through losses in the system. These losses are predicted by the equation:

P=I²R

Where P is the power (or, in this case, the amount of power lost), I is the current running through the transmission circuit, and R is the resistance of the transmission circuit. From this equation, it can be seen that reducing the value of the current, I, would result in a corresponding reduction in power lost, P. One method of lowering the current in a circuit is to increase the voltage, as shown by the formula:

P=VI

Where V is the voltage or potential difference in the transmission circuit. By increasing the voltage, V, the resulting current, I, for the same power, P, must drop. Therefore, stepping the transmission voltage up significantly helps reduce the power lost in transmission. Unfortunately, at the time of Edison, there was no convenient way to change the voltage level in a DC system, and so AC transmission systems became the norm. However, transmission over high-voltage AC transmission lines has limitations, especially when compared to transmission over high-voltage DC transmission lines. These limitations include a higher number of conductors required, a larger “footprint” for cross-country transmission lines, larger power losses over the length of the lines, a higher cost to operate and maintain, and significant difficulty in synchronizing AC generators, among other limitations.

The development of high-power switching, allowing high-power AC voltages to be converted to high-power DC voltages, enabled the use of high-voltage DC transmission systems where it had been historically impractical or impossible. High-power switching has been dominated by devices using gas plasmas such as mercury arc rectifiers and semiconductors such as thyristors and transistors, but these devices each have unique disadvantages.

Plasma devices require special control circuits, efficient cooling methods, and careful operation to avoid internal conditions (like abrupt or uneven geometry in conductors) or external voltage patterns which can initiate an arc at the wrong time. In addition, once an arc is initiated, the device cannot be turned off until the voltage is low enough that the arc can no longer be sustained. The arc consumes a large amount of power over a large minimum voltage drop which limits efficiency. The arc is also relatively slow to start. For these reasons, plasma discharge devices have largely been displaced by modern switching equipment such as high-power semiconductors.

Semiconductors such as Insulated Gate Bipolar Transistors (IGBT) work up to a few thousand volts. They switch on quickly but switch off slowly and must be protected from overcurrent or other conditions which cause “latch up,” which is a failure to turn off. Since their operating voltage is much lower than that of modern transmission lines, multiple devices must often be cascaded to control the actual voltage. This cascade can multiply the voltage drops and limit the overall efficiency. The need to avoid latch-up overload and the slow turn off add complexity to designs. These complexities can add to the cost, size, inefficiencies, and operational limitations of semiconductor high voltage power switches.

Vacuum tubes with thermionic cathodes (classical vacuum tube triodes, for example) never gained a foothold in the high-power switching application because thermionic cathodes broad enough to supply the current needed for the high currents would be difficult to heat, and inefficient because of the power lost to this heating. Additionally, the cathodes can remain hot for a long time, even if the heater is switched off, which can prevent them from switching off quickly under voltages high enough to sustain an arc. Trying to control such voltages with a grid when the supply of electrons is still hot will often result in the grid being burned out. These drawbacks effectively prevent thermionic vacuum tubes from being used in high-power conversion equipment.

The prior methods of high-power, high-voltage switching have significant drawbacks and inefficiencies. With the increasing importance of a smart electrical grid capable of transmitting power over increasing distances, there exists a need for an improved high-voltage rectification system and method to overcome the aforementioned obstacles and deficiencies of conventional high-power switching systems.

### BRIEF DESCRIPTION OF THE DRAWINGS

FIG. 1A is an exemplary diagram illustrating an embodiment of a high-power transmission system in which an embodiment of a controlled photo-electric switch may be used.

FIG. 1B is an exemplary diagram illustrating an embodiment of an electrical circuit for the conversion of high-voltage AC power to high-voltage DC power.

FIG. 1C is an exemplary diagram illustrating an embodiment of an electrical circuit for the conversion of high-voltage DC power to high-voltage AC power.

FIG. 2 is an exemplary diagram illustrating an alternate embodiment of a controlled photo-electric switch.

FIG. 3 is an exemplary diagram illustrating an alternate embodiment of a controlled photo-electric switch in which reflective surfaces are used to direct light onto a cathode.

FIG. 4 is an exemplary diagram illustrating an alternate embodiment of a controlled photo-electric switch in which a control ring is used to facilitate electron flow toward an anode and the photo-cathode surface is on the front of a transparent substrate which is illuminated from behind.

FIG. 5 is an exemplary diagram illustrating an alternate embodiment of a controlled photo-electric switch with an alternate form factor and a control grid for controlling the acceleration of electron flow.

FIG. 6 is an exemplary diagram illustrating an alternate embodiment of a controlled photo-electric switch featuring a heat sink attached to the photo-cathode for cooling.

FIG. 7 is an exemplary diagram illustrating an alternate embodiment of a controlled photo-electric switch featuring internal shades that can protect the walls from sources of contamination such as sputtering of material.

FIG. 8 is an exemplary diagram illustrating an alternate embodiment of a controlled photo-electric switch configured for ease of manufacture.

It should be noted that the figures are not drawn to scale and that elements of similar structures or functions are generally represented by like reference numerals for illustrative purposes throughout the figures. It also should be noted that the figures are only intended to facilitate the description of the preferred embodiments. The figures do not illustrate every aspect of the described embodiments and do not limit the scope of the present disclosure.

### DETAILED DESCRIPTION OF THE PREFERRED EMBODIMENTS

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

Techniques described and suggested include methods and systems for controlling the flow of electrical current, and in particular to the switching of electrical current in a high-voltage system. Example embodiments can be used in conversions between high-voltage Direct Current (DC) power and high-voltage Alternating Current (AC) power, or conversions between different voltages of DC power, or conversions between different voltages of AC, or regulating and protecting high-voltage electrical power circuits and equipment. In high-voltage operation, the methods and systems described can offer advantages in efficiency, high-frequency operation, and switching speed and performance.

For the purposes of this specification, the term “high-voltage” shall be defined generally as a voltage of electrical energy high enough to inflict harm on living organisms. More practically, the International Electrotechnical Commission (IEC) defines “high-voltage” to be anything above 1000 volts for alternating current and above 1500 volts for direct current. In the transmission of electric power, “high-power” is generally considered to be anything over 35,000 volts.

Various example embodiments are directed to a switch, which can be an electrical device used for converting an alternating current into a direct current by allowing current to flow through it in only one direction. In some embodiments, a switch provides two electrodes, a photo-cathode and an anode, separated by a distance in a sealed vacuum tube. A photo-cathode can be a negatively charged electrode that emits electrons when illuminated by a light source due to the photoelectric effect, or photoemission. In photoemission, energy from photons striking the surface of the photo-cathode can be acquired by electrons within the material of the photo-cathode, causing the electrons to be ejected. When the photo-cathode is illuminated, electrons can be emitted, flowing through the interior of the vacuum tube to the positively charged anode, creating a flow of current between the two electrodes. In some embodiments, electrons are sourced only from the photo-cathode, so the switch can be polarized for electron flow from photo-cathode to anode.

It should be noted that the term “switch” should not be construed to be limiting in any way, and that embodiments of the present disclosure can be used in other suitable applications outside of the conversion between alternating current and direct current. Various embodiments can be used in any suitable application requiring the switching of electrical current, and some preferred embodiments can be configured for high-power current switching applications. The various embodiments can also be well suited for the modulation of power, as described herein.

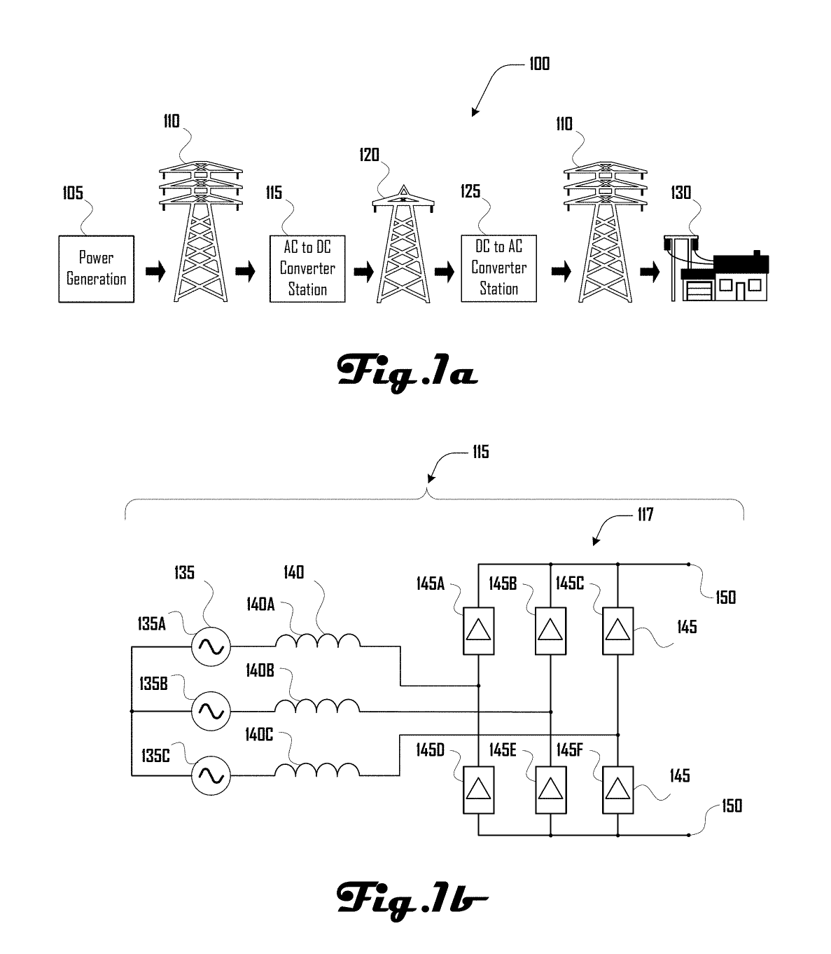

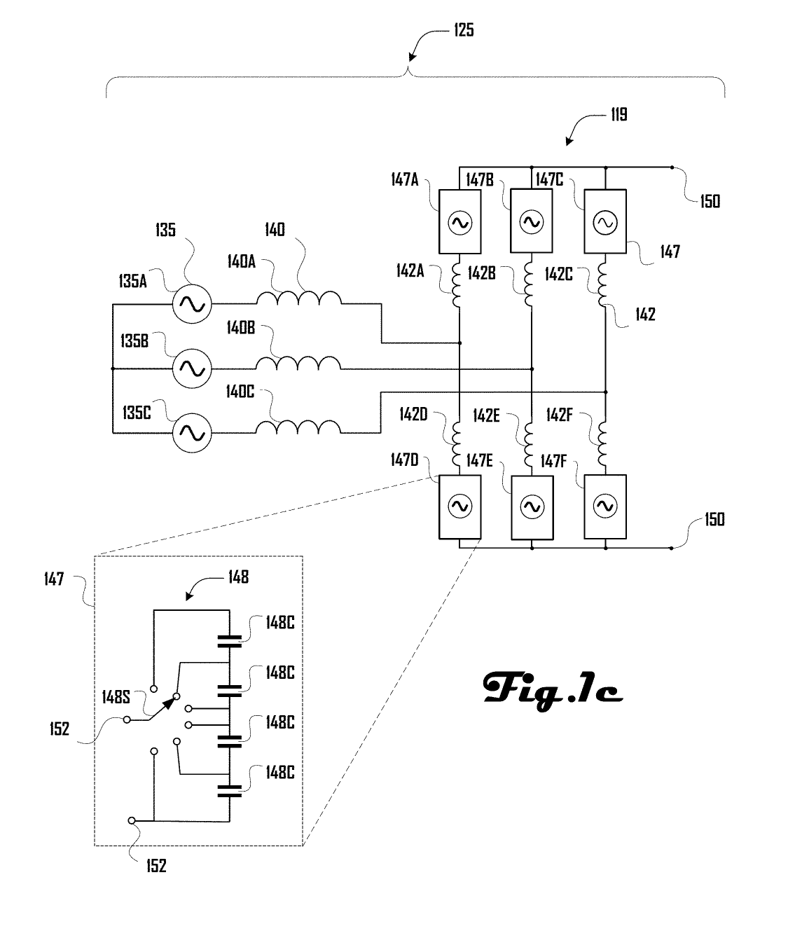

Turning now to the figures, various embodiments of the photo-electric switch will be described in more detail. FIG. 1A is an exemplary diagram illustrating an embodiment of a high-power transmission system in which an embodiment of the photo-electric switch can be used. The diagram shows an example transmission path for power from the source of the power (for example, a power generation plant or source of renewable energy) to the distribution lines that deliver power to the end customers (for example, businesses and homes).

High-voltage alternating current (HVAC) power can be generated at a power generation source 105. The power generation source 105 can be a power plant (for example, a hydroelectric dam, a fossil fuel power station, a nuclear power plant, a wind farm, or the like). The HVAC power generated at the power generation source 105 can be directly attached, or carried over AC transmission lines 110, to an AC to DC converter station 115 (also known as a rectification station). The AC to DC converter station 115 then converts the HVAC electric power to high-voltage direct current (HVDC) power, which can then be transmitted long distances over DC transmission lines 120. Power transmission using HVDC can have advantages over transmission using HVAC as previously discussed herein, but these advantages include requiring fewer transmission towers, smaller, less expensive transmission towers, and a smaller environmental impact (smaller “footprint”).

The DC transmission lines 120 deliver the HVDC power to a DC to AC converter station 125 (also known as an inversion station), where the HVDC power is converted back into HVAC power. The HVAC power can then be carried over another set of AC transmission lines 110 and delivered to distribution lines 130, where the power is stepped down using transformers to voltage levels appropriate for end customers (businesses, homes, etc.).

For the purposes of this specification, the AC to DC converter station 115 and the DC to AC converter station 125, as well as converter stations which convert from one level of AC power to another level of AC power, or from one level of DC power to another level of DC power, shall collectively be referred to as “power conversion stations.” However, the term “station” should not be construed to be limiting in any way, and is not meant to imply or require a specific architectural structure or embodiment. As used herein, a “power conversion station” shall be synonymous and interchangeable with the term “power conversion circuit.”

The high-voltage switch, which will be described in detail herein, can be a component of the AC to DC converter station 115 and/or the DC to AC converter station 125 of FIG. 1A. The high-voltage switch acts as an electrical switch which allows current to flow through it in one direction, and this property allows the switch to be used in the rectification and inversion processes needed to convert from HVAC to HVDC and back again. This is best illustrated by examples, such as those shown in FIGS. 1B and 1C.

(It should be noted that, although a typical switch allows current to flow through it in one direction only, it would be possible to construct a switch using the principles described herein that would allow current to pass in both directions, as dictated by the needs of the application.)

Turning now to FIG. 1B, we see an example embodiment of the high-voltage AC to DC converter station 115 of FIG. 1A. Note that the embodiment shown in FIG. 1B is an example only for teaching purposes and not meant to be limiting in any way.

An exemplary AC to DC converter station 115 can implement a power conversion circuit as shown in FIG. 1B. This power conversion circuit takes in three phases, with each phase having an AC generator 135 and an inductor 140. Each phase of the generator 135 outputs an AC voltage signal across the inductors 140 which is a sine wave, with the voltage generated constantly changing from 0 volts up to a maximum positive voltage, then decreasing back down to 0 volts where the voltage becomes negative, then the voltage changes down to a maximum negative voltage and then returns back to 0 volts again.

The AC phase voltages seen on inductors 140A, 140B, and 140C are connected to a switch circuit 117 comprising (in this example) six switching elements or valves 145. These valves 145 allow current to flow in only one direction, as indicated by the direction of the triangle shown on each valve 145. In normal operation, only two of the six valves 145, one from the top row (values 145A, 145B, and 145C) and one from the bottom row (145D, 145E, and 145F), are conducting (allowing current to pass) at any one time. In this manner, the two conducting valves 145 connect two of the three AC phase voltages seen at the inductors 140 in series. For example, if valves 145A and 145F are conducting, the DC output voltage seen across terminals 150 would be calculated as the voltage across inductor 140A minus the voltage across inductor 140C. The combination of valves shown in the example of FIG. 1B can be used for converting three phase HVAC into HVDC.

Turning now to FIG. 1C, we see an example embodiment of the high-voltage DC to AC converter station 125 of FIG. 1A. Note that the embodiment shown in FIG. 1C is an example only for teaching purposes and not meant to be limiting in any way.

An exemplary DC to AC converter station 125 can implement a power conversion circuit as shown in FIG. 1C. The power conversion circuit shown is an example of a modular multi-level converter (MMC). In some embodiments, an MMC power conversion circuit uses a number of valve submodules 147 and inductors 142 (such as shown in subcircuit 119) to convert DC power seen at terminals 150 into three-phase AC power at phases 135. Each valve submodule 147 acts as a controllable voltage source capable of generating various levels of voltage. Each valve submodule 147 does this by implementing switching circuit 148, shown in the close up view of valve 147 shown in the lower left of FIG. 1C. Each switching circuit 148 can be comprised of a number of capacitors 148C. Each capacitor 148C is either bypassed or connected into the switching circuit 148 by switch 148S. One possible implementation of switch 148S uses one or more embodiments of the high-voltage photo-electric switch described herein.

By controlling the timing and state of switch 148S, various combinations of storage capacitors 148C can be included in switching circuit 148, creating varying levels of voltage across output terminals 152. These varying levels of voltage can be used to create a stepped voltage waveform that approximates the sine wave of an AC signal.

The valves 145 of FIG. 1B can be unidirectional switches, each of which can allow current to flow through them in the direction indicated when engaged. One possible implementation of these valves 145 is one or more embodiments of the high-voltage photo-electric switch described herein. Similarly, one or more embodiments of the high-voltage photo-electric switch described herein can be used to implement the switching circuit 148 of FIG. 1C. Various embodiments of the high-voltage photo-electric switch will now be described in the remaining figures.

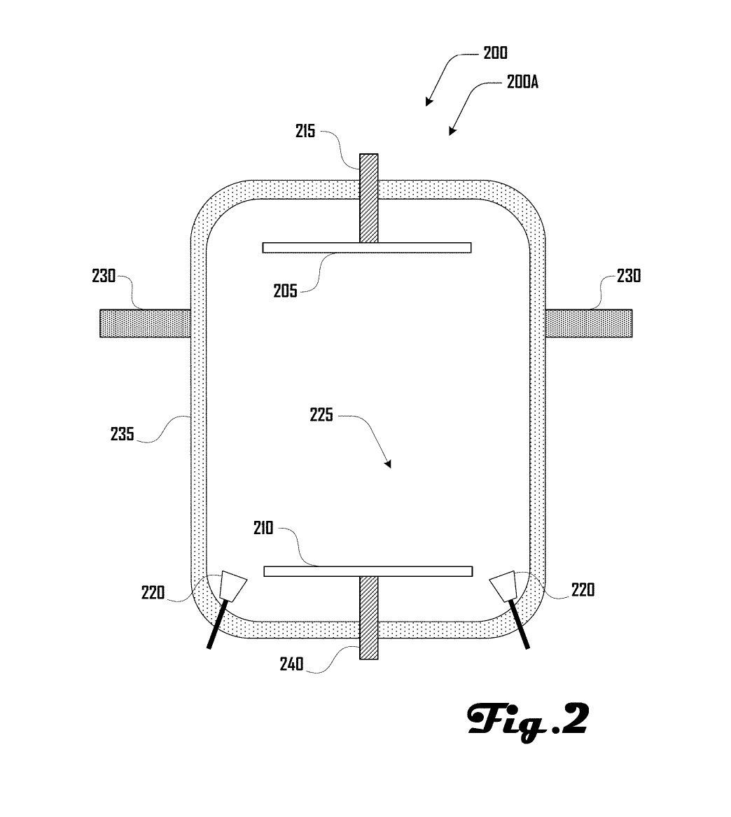

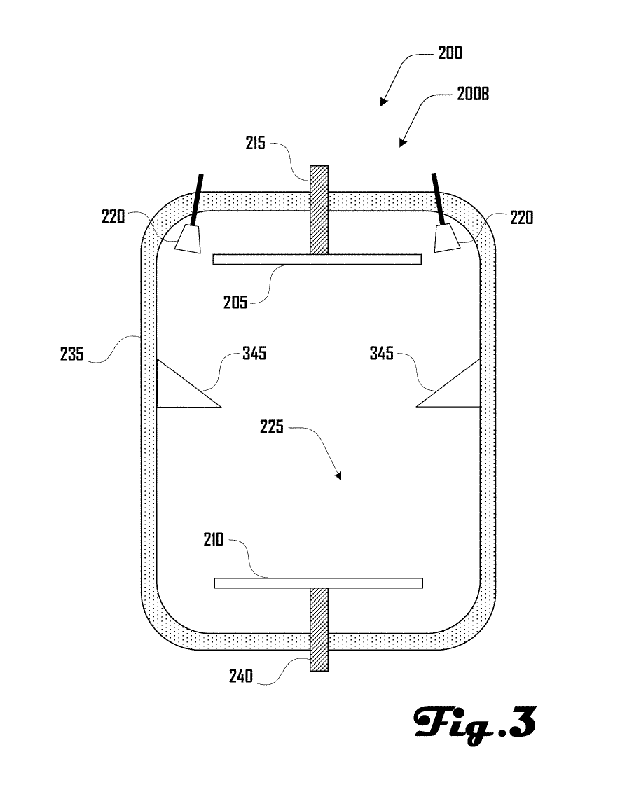

FIG. 2 is an exemplary diagram illustrating one embodiment of a controlled photo-electric switch 200. It should be noted that the reference designator 200 will be used throughout the specification to refer to the photo-electric switch in general terms, and various embodiments of the photo-electric switch, as shown in FIGS. 2-8, will each have a letter added to the reference designator to distinguish it from other embodiments. For example, the embodiment of the photo-electric switch 200 shown in FIG. 2 shall be alternately referred to as 200A, and the embodiment of the switch 200 shown in FIG. 3 shall be alternately referred to as 200B. It should also be noted that the photo-electric switch 200 can be used as the implementation of the valves 145 in FIG. 1B.

Returning to FIG. 2, an input electrical conductor 215 connects to a photo-cathode 205. The end of the electrical conductor 215 not connected to the photo-cathode 205 can be connected to an external electrical circuit (not shown), such as the rectification circuit 117 illustrated in FIG. 1B. The photo-cathode 205 can be separated by a vacuum 225 from a conductive anode 210, which in turn can be connected to an output electrical conductor 240 connected to an external electrical circuit (not shown). The external electrical circuit (not shown, but an example rectification electrical circuit 117 is shown in FIG. 1B) applies a voltage between photo-cathode 205 and the anode 210. The photo-electric switch 200 will control the flow of electrical current between the photo-cathode 205 and the anode 210.

Photo-cathode 205 surfaces emit electrons when the energy per photon is comparable to or greater than the electronic work function characteristic of the surface. This transition is not exact because some electrons will have additional thermal energies or benefit from local variations in the surface, but in general photons with energy much less than the nominal work function will not enable electrons to be released.

Various embodiments of the photo-electric switch 200 include light sources 220 capable of emitting light of a wavelength where the photon energy is sufficient to stimulate emission of electrons from the photo-cathode 205. In one example embodiment, this light can be provided by light emitting diodes (LEDs) with an optical path which leads the light to the photo-cathode 205. In another example embodiment, the light sources 220 can be a laser. It would be understood by one skilled in the art that any appropriate source of photons can be used, subject to the requirement that the wavelength of the light include photons with energy greater than the work function of the electron photo-emission surface (the photo-cathode 205). In some example embodiments, the amount of light emitted by light sources 220 can be modulated in pulse frequency and/or intensity to best control the photo-electric switch 200.

In some example embodiments, light sources 220 can be located inside a vacuum tube, also known as a vacuum chamber 235, positioned either to shine directly on the surface of the photo-cathode 205 facing anode 210 or to shine through the photo-cathode 205 from behind (as in the case of a transmission type photo-cathode, to be discussed later). In other example embodiments, reflective surfaces can be installed in the vacuum chamber 235 to create a path for photons such that they strike the surface of the photo-cathode 205 with optimal efficiency, no matter their position relative to the emissive photo-cathode 205 surface. In yet other example embodiments, the source of illumination 220 can be located outside the vacuum chamber 235 with the light being directed into the interior of the vacuum chamber 235 and the photo-cathode 205 through transparent or translucent vacuum chamber 235 walls.

Some embodiments of the switch 200 also allow for illumination by light at wavelengths with photon energy which is too low or at the wrong wavelength to initiate photo-emission. This light is called “ineffective light,” and can be used for purposes including, but not limited to, visual inspection of the switch 200 or generation of power for components of the switch 200 through the use of photocells.

For example, some of the most efficient and durable photo-cathodes 205 require ultraviolet light to cause electron emission and so light in the human-visible spectrum can be considered “ineffective.” Ineffective light can be present within the device or in the general vicinity of the device and surrounding equipment without causing electrons to be emitted from the photo-cathode 205.

As previously described herein, light sources 220 can provide light of a wavelength short enough that the photon energy of the light exceeds the energy which is needed to cause the photo-cathode 205 to emit electrons through the photo-electric effect. The intensity of light sources 220 can determine the number of electrons which can be emitted from the photo-cathode 205. If light sources 220 are switched off, then the photo-electric effect will be stopped and no electrons will be emitted by the photo-cathode 205. The photo-electric switch 200 can be configured, in some embodiments, such that any ambient light striking the photo-cathode 205 (such as human-visible light shining into the photo-electric switch 200) will be of a wavelength associated with lower photon energy (ineffective light, as previously described) such that photo-emission will not be initiated.

The photo-cathode 205 and the anode 210 are enclosed in a sealed vacuum chamber 235. The vacuum chamber 235 can be constructed of a durable, electrically insulating material and sealed and evacuated such that it creates a high-quality vacuum 225. For the purposes of this specification, the terms “vacuum” and “high-quality” vacuum” shall be used to define a vacuum of a quality such that there are not enough free-floating atoms within the vacuum chamber 235 to sustain an arc. In this way, when photons are not available from light sources 220, the vacuum 225 will not allow any current to flow between the photo-cathode 205 and the anode 210 even if the voltage differential between the photo-cathode 205 and the anode 210 is very high. The material from which the vacuum chamber 235 is constructed can be a good electrical insulator, made from materials with will not readily decay, evaporate, or otherwise shed material which might contaminate the surfaces contained within the photo-electric switch 200 and lead to unwanted electrical conduction pathways. In various embodiments, it can be desirable for the interior surfaces of the vacuum chamber 235 to be free of contaminants during operation to prevent additional electrical conduction pathways.

The current flow in the switch can be modulated by the amount of light falling upon the photo-cathode. For example, in some embodiments, current flow is reduced to zero when light is removed from the photo-cathode 205. Photoemission from the cathode 205 is a quantum process, allowing fast switching speeds in some embodiments, including but not limited to on the order of tens of picoseconds. The process of conversion from light to electrons can be almost perfectly linear, so some embodiments can be used to modulate power, as well as to switch it.

Some photo-cathode 205 materials can permit construction of a broad photo-cathode 205 surface which in some embodiments can supply several hundred amperes of current, given adequate illumination. In some embodiments, there can be a distance separating the photo-cathode 205 from the anode 210, allowing for voltage to be blocked by the vacuum gap 225. For example, in some preferred embodiments, the distance separating the photo-cathode 205 from the anode 210 can be on the order of centimeters including 1 cm, 5 cm 10 cm, 50 cm, or the like. In further preferred embodiments, the voltage blocked by the vacuum gap can be on the order of hundreds of thousands of volts, including 10,000 volts, 50,000 volts, 150,000 volts, or the like. This can make it possible for some embodiments to switch megawatts of power with a single switch device 200. In some embodiments, upper power limits for a device are set by the ability to remove heat from the switch 200 and by the voltages which the external electrical loads may generate in opposition to fast switching. Although some embodiments described herein can include a distance separating the photo-cathode 205 from the anode 210 on the order of centimeters, further embodiments, can include such a distance on the order of millimeters, decimeters, meters, or the like. Additionally, although some embodiments relate to a voltage blocked by a vacuum gap can be on the order of hundreds of thousands of volts, further embodiments blocked voltage can include 100 volts, 500 volts, 1,000 volts, 5,000 volts, or the like.

The photo-cathode 205 can comprise various suitable materials. For example, in some embodiments, the photo-cathode 205 can be constructed from a material capable of photo-emission, including, but not limited to, S1 (Ag—O—Cs), antimony-cesium (Sb—Cs), bialkali (Sb—Rb—Cs/Sb—K—Cs), high-temperature or low-noise bialkali (Na—K—Sb), multialkali (Na—K—Sb—Cs), gallium-arsenide (GaAs), indium-gallium-arsenide (InGaAs), cesium-telluride (Cs—Te), cesium-iodide (Cs—I), and gallium-nitride (Ga—N), or the like.

In one example embodiment, a photo-cathode constructed of a gallium-nitride material with a trace layer of cesium can be used in conjunction with ultraviolet light (photons) with a wavelength shorter than 357 nm (more than 3.5 eV photon energy).

Photo-cathode 205 materials can be selected based on the desired performance characteristics of the photo-cathode 205, including but not limited to the desired spectral response, thermoelectric and mechanical properties, and whether the photo-cathode 205 is a transmission type or a reflective type. Many different photo-cathode 205 materials exist and may be appropriate for use in the photo-cathode 205 of various embodiments. Some of these materials are best adapted for front illumination, while others work best with rear illumination.

Photo-cathodes 205 can include transmission and reflective photo-cathodes 205. A transmission type photo-cathode 205 can be defined by a photo-cathode 205 where light strikes one surface or side of the photo-cathode 205 and electrons exit from the opposite surface or side. A transmission type photo-cathode 205 can be constructed by coating a transparent window with a photo-emissive coating which allows light to pass through, causing electrons to be ejected on the opposite surface from which the light is shone. Generally, for the purposes of discussion, the side of a transmission type photo-cathode 205 being illuminated shall be considered the “back side” of the photo-cathode 205, and the side from which electrons are emitted (that is, the side facing the anode 210) shall be considered the “front side.”

A reflective type photo-cathode 205 can be defined by a photo-cathode 205 in which the light enters and the electrons exit from the same surface or side of the photo-cathode 205. In some embodiment, a reflective type photo-cathode 205 can be formed on an opaque metal electrode base. A variation on the reflective type photo-cathode 205 can include a double reflection type, where the metal base can be mirror-like, causing light that passed through the photo-cathode 205 to be reflected back through the photo-cathode 205 for another try at imparting energy to the electrons in the base material. In some embodiments, a specialized coating which releases electrons more readily than the underlying material of the photo-cathode 205 base can be applied to the photo-cathode 205 to increase the photo-electric effect.

In various embodiments, the anode 210 operates at a positive voltage relative to the photo-cathode 205. The anode 210 can be any appropriate conductor or semiconductor material known to those in the arts capable of receiving current flow. In some embodiments, the anode 210 can be constructed from a material, including but not limited to, tungsten, or the like, to improve the thermodynamic performance of the anode 210 (for example, to absorb heat during switch shut-off).

Electrons emitted by the photo-cathode 205 can be attracted across the vacuum to the positive voltage of the anode 210, creating current flow. In some example embodiments, the anode can be narrower or wider than the cathode. In some example embodiments, the anode 210 can be a copper plate parallel to the photo-cathode 205. In other example embodiments, a copper plate with a carbon or carbide alloy coating on the surfaces where electrons arrive can be used. In some embodiments, using a carbon or carbide alloy coating on the anode 210 can have a low rate of sputtering or ion emission under electron impact.

In another example embodiment, the anode 210 can be tungsten if the device needs to be tough enough to absorb high energy pulses during switching events or to operate with limited current resulting in high voltage between the photo-cathode 205 and anode 210. In another example embodiment, the anode 210 can itself comprise a photo-cathode 205, so that the device may operate to conduct current in both directions.

The photo-electric switch 200 can be installed in an electrical circuit (such as the example circuit of FIG. 1B) such that it is surrounded by a collar of insulating material 230, to avoid current bypassing the device. This electrical isolation can also be achieved by surrounding the photo-electric switch 200 itself with a vacuum. The photo-electric switch 200 should also be installed so as to avoid the creation of electrically conductive pathways with external surfaces and surrounding equipment.

When a high vacuum is established within the photo-electric switch 200, and all surfaces are properly insulated or isolated, electricity can only flow when the light sources 220 are on and causing electrons to be emitted from the photo-cathode 205 through the photo-electric effect. In some embodiments, the current can only flow in one direction, when the photo-cathode 205 potential is sufficiently negative relative to the anode 210. The amount of current flowing through the device depends upon the number of electrons released by the photo-cathode 205, and is therefore modulated by the intensity of the light sources 220.

FIGS. 3 through 8 provide illustrations of alternate embodiments of the photo-electric switch 200. Reference designators have been maintained through the various embodiments, such that a component common to two or more figures will use the same reference designator. Various embodiments of the photo-electric switch 200 shall be alternately labeled 200A through 200G in FIGS. 2-8 to distinguish the different examples provided. As previously noted, the figures are only intended to facilitate the description of the preferred embodiments, and do not illustrate every aspect of the described embodiments and should not be construed to limit the scope of the present disclosure.

FIG. 3 illustrates an alternate embodiment 200B of the controlled photo-electric switch 200 of FIG. 2 in which reflective surfaces 345 are used to direct light onto a cathode. A photo-cathode 205 can be connected to an input electrical conductor 215. An anode 210 can be connected to an output electrical conductor 240. The photo-cathode 205 can be separated from the anode 210 by a vacuum 225 contained inside a vacuum chamber 235. As with embodiment 200A of FIG. 2, photo-electric switch 200B can be connected via input electrical conductor 215 and output electrical conductor 240 to an external electrical circuit (not shown), which can apply a voltage between the photo-cathode 205 and the anode 210.

In some embodiments of the photo-electric switch 200, such as the example embodiment 200B of FIG. 3, it may be more convenient or otherwise advantageous to mount the light sources 220 on the same end of the vacuum chamber 235 as the photo-cathode 205. This can be for reasons such as ease of manufacturing or maintenance, or other considerations such as positioning of components to avoid sputtering or unintended arcing. In the embodiment of the photo-electric switch 200B shown here, reflective elements 345 are positioned inside the vacuum chamber 235 such that light emitted by light sources 220 is directed onto the photo-emissive surface of photo-cathode 205. The reflective elements 345 can be mirrors, lenses, polished surfaces, or other optical elements which redirect the light onto the photo-emissive surface of the photo-cathode 205. In some embodiments, the reflective elements 345 can be made with insulating materials and configured to prevent unintended arcing or material sputtering. For example, a dichroic mirror can be made using alternating layers of insulating materials with thicknesses chosen to reflect the appropriate wavelength of the illumination.

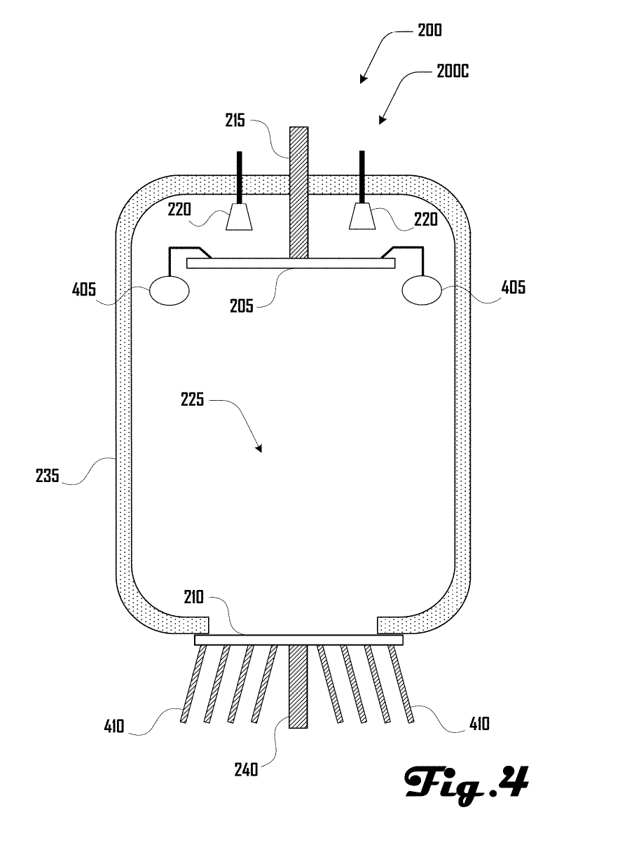

FIG. 4 illustrates an alternate embodiment 200C of the controlled photo-electric switch 200 of FIG. 2 in which a control ring 405 is used to facilitate electron flow toward the anode 210. A photo-cathode 205 can be connected to an input electrical conductor 215. An anode 210 can be connected to an output electrical conductor 240. The photo-cathode 205 can be separated from the anode 210 by a vacuum 225 contained inside a vacuum chamber 235. As with embodiment 200A of FIG. 2, photo-electric switch 200C can be connected via input electrical conductor 215 and output electrical conductor 240 to an external electrical circuit (not shown), which can apply a voltage between the photo-cathode 205 and the anode 210.

In the example embodiment 200C of FIG. 4, the photo-cathode 205 can be a transmission type cathode as previous described herein, allowing photons emitted by light sources 220 to enter through the back side of the photo-cathode 205, passing through the photo-cathode 205, imparting energy to the electrons in the photo-cathode 205 and initiating photo-emission of electrons toward the anode 210. This allows the light sources 220 to be installed behind the photo-cathode 205 as shown in the embodiment of FIG. 4.

The embodiment of the photo-electric switch 200C may also include one or more control rings 405, shown in FIG. 4 in cross section. The control rings 405 may surround the photo-cathode 205, or alternately surround the space between the photo-cathode 205 and the anode 210, and may have a donut shape, although one skilled in the art will understand that this is only one of many possible shapes and configurations. The control rings 405 can be constructed of a material similar to that used in the construction of the anode 210. For example, in some embodiments the control rings 405 can comprise any appropriate material which is electrically conductive and which does not readily shed materials which may contaminate the interior of the vacuum chamber 235. As previously described, the control rings 405 can have a zero or negative voltage relative to the photo-cathode 205, allowing them to be used to steer electrons toward the anode 210 and reduce stray electrons reaching the walls of the vacuum chamber 235.

The photo-electric switch 200C illustrates an alternate method of sealing the anode 210 to one end of the vacuum chamber 235, in which the anode 210 can be used to form a seal against an opening in the vacuum chamber 235. Photo-electric switch embodiment 200C also illustrates the addition of a cooling architecture 410 to remove excess heat from the anode 210. The cooling architecture 410 can be any appropriate architecture of active or passive cooling, including but not limited to radiators, heat pipes, coolant conduits, or any appropriate architecture for removing, absorbing, or redirecting heat. The example embodiment 200C shows projections such as aluminum fins to provide passive air cooling, but this is an example only and should not be construed to be limiting in any way.

Some electrodes (such as photo-cathode 205 or anode 210) may withstand heat well enough to operate with passive radiative and conductive cooling through the conductors and packaging. Some high power designs may use cooling systems capable of removing additional amounts of heat, such as heat pipes or circulated coolants. Alternatively, some high power designs may have physically large electrodes made of materials which operate at very high temperatures such that large amounts of energy can be absorbed from switching or controlling large loads.

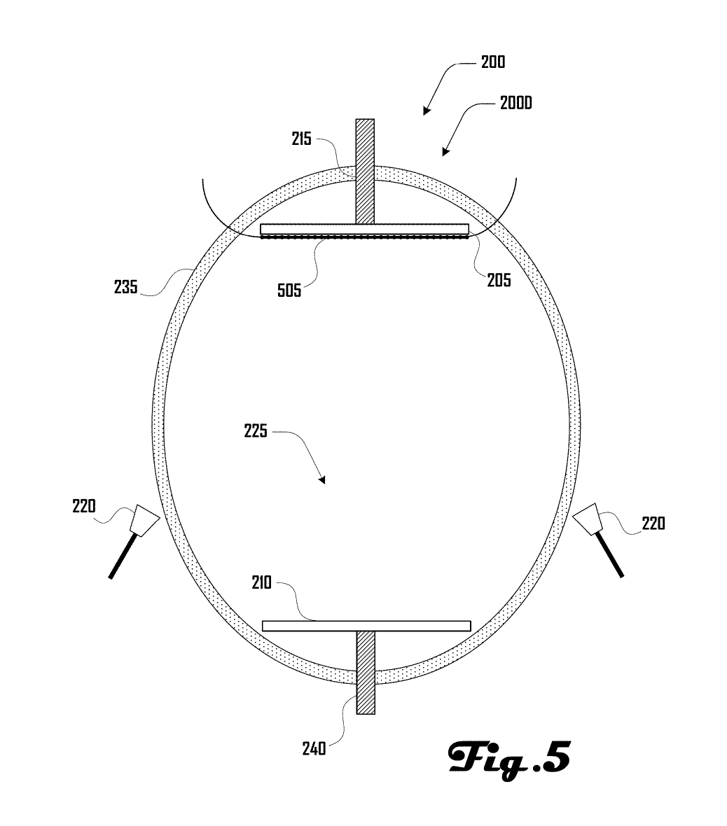

FIG. 5 illustrates an alternate embodiment 200D of the controlled photo-electric switch 200 of FIG. 2 with an alternate form factor and a control grid 505 for controlling the acceleration of electron flow. A photo-cathode 205 can be connected to an input electrical conductor 215. An anode 210 can be connected to an output electrical conductor 240. The photo-cathode 205 can be separated from the anode 210 by a vacuum 225 contained inside a vacuum chamber 235. As with embodiment 200A of FIG. 2, photo-electric switch 200D can be connected via input electrical conductor 215 and output electrical conductor 240 to an external electrical circuit (not shown), which can apply a voltage between the photo-cathode 205 and the anode 210.

Photo-electric switch 200D shows the addition of an optional control grid 505 a short distance away from and over the photo-cathode 205. In some embodiments, control grid 505 can be configured as a fine conductive mesh placed near to and substantially parallel with the photo-cathode 205. The control grid 505 can have a small positive voltage relative to the photo-cathode 205, and can be used to accelerate electrons away from the photo-cathode 205 toward the anode 210. The control grid 505 can allow electrons to cross a relatively large distance through the vacuum chamber 235 to the anode 210 at low voltage and high efficiency. The control grid 505 can allow for low positive voltages at both the control grid 505 and the anode 210, while maintaining a steep gradient just above the photo-cathode 205 to draw electrons into the vacuum chamber 235 toward the anode 210. The use of low voltages can promote more efficient operation of the photo-electric switch 200D. In some embodiments, the control grid 505 may also be used, with or combined with varying illumination levels, to suppress current flow by applying a negative voltage to the control grid 505 relative to the photo-cathode 205.

Photo-electric switch 200D also shows light sources 220 being mounted external to the vacuum chamber 235. This suggests that the walls of the vacuum chamber 235 be transparent or at least translucent so that illumination reaches the photo-cathode 205 in sufficient quantity to initiate photo-emission.

Finally, the vacuum chamber 235 in photo-electric switch 200D is shown with a different form factor than that of previous embodiments. In this example, the form factor of the vacuum chamber 235 can be ovoid or spherical. This form factor, as well as any shown in the other drawings, are intended to be exemplary and are not intended to be construed as limiting in any way.

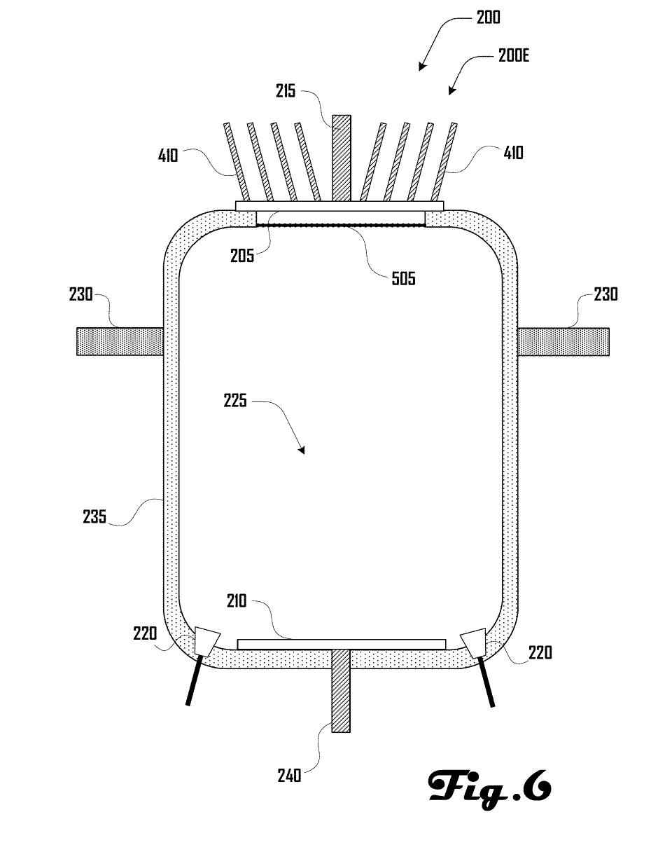

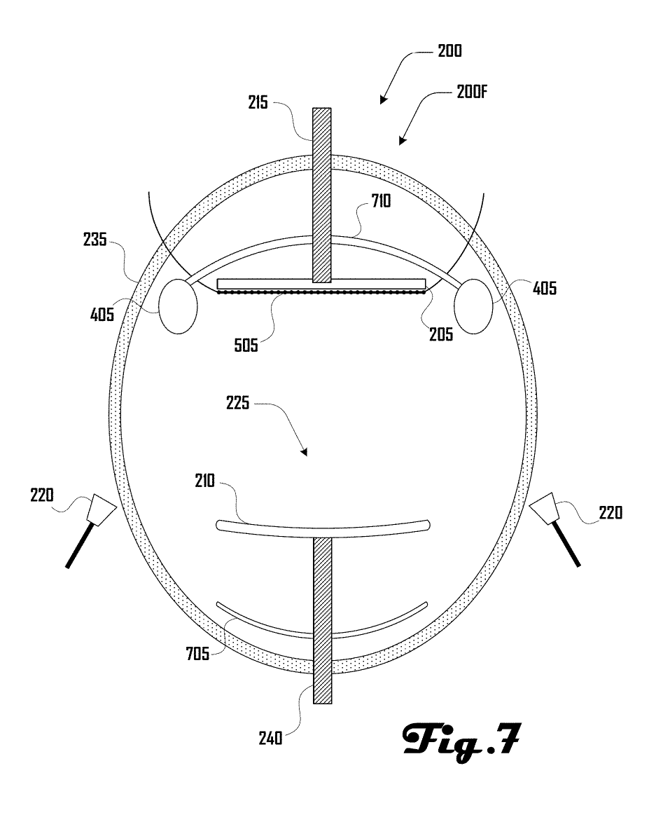

FIG. 6 illustrates an alternate embodiment 200E of the controlled photo-electric switch 200 of FIG. 2 featuring a cooling architecture (for example, a heat sink) 410 attached to the photo-cathode 205 for cooling. A photo-cathode 205 can be connected to an input electrical conductor 215. An anode 210 can be connected to an output electrical conductor 240. The photo-cathode 205 can be separated from the anode 210 by a vacuum 225 contained inside a vacuum chamber 235. As with embodiment 200A of FIG. 2, photo-electric switch 200D can be connected via input electrical conductor 215 and output electrical conductor 240 to an external electrical circuit (not shown), which can apply a voltage between the photo-cathode 205 and the anode 210. An optional control grid 505 can be used to accelerate and steer the flow of electrons between the photo-cathode 205 and the anode 210.

In embodiment 200E, both the light sources 220 and anode 210 are shown integrated into and sealed to the wall of the vacuum chamber 235. In this embodiment, the photo-cathode 205 is shown mounted and sealed to an opening in the wall of the vacuum chamber 235. These alternate methods of mounting components are provided for illustrative and exemplary purposes, and are not meant to be construed as limiting in any way. One skilled in the art would see that it would be possible to combine any number of mounting and sealing methods into the photo-electric switch without deviating from the concepts described herein.

In embodiment 200E, a cooling architecture 410 can be attached to the back side of the photo-cathode 205. The cooling architecture 410 can be any appropriate architecture of active or passive cooling, including but not limited to radiators, heat pipes, coolant conduits, or any appropriate architecture for removing, absorbing, or redirecting heat. The example embodiment 200E shows projections such as aluminum fins to provide passive air cooling, but this is an example only and should not be construed to be limiting in any way.

FIG. 7 illustrates an alternate embodiment 200F of a controlled photo-electric switch featuring internal shades 705 and 710 to protect the walls from sputtering of material. A photo-cathode 205 can be connected to an input electrical conductor 215. An anode 210 can be connected to an output electrical conductor 240. The photo-cathode 205 can be separated from the anode 210 by a vacuum 225 contained inside a vacuum chamber 235. As with embodiment 200A of FIG. 2, photo-electric switch 200F can be connected via input electrical conductor 215 and output electrical conductor 240 to an external electrical circuit (not shown), which can apply a voltage between the photo-cathode 205 and the anode 210. An optional control grid 505 can be used to accelerate and steer the flow of electrons between the photo-cathode 205 and the anode 210. An optional control ring 405 can surround the photo-cathode 205, or alternately surround the space between the photo-cathode 205 and the anode 210, and can have a donut shape, although one skilled in the art will understand that this is only one of many possible shapes and configurations. As previously described, the control ring 405 can have a zero or negative voltage relative to the photo-cathode 205, allowing it to be used to steer electrons toward the anode 210 and reduce stray electrons reaching the walls of the vacuum chamber 235.

In addition to the control ring 405, the walls of the vacuum chamber 235 can be protected from the sputtering of material by optional shades 705 and 710. As shown in FIG. 7, shades 705 and 710 can be arranged as a curved circular plate, similar in shape to an open umbrella (shown in FIG. 7 in cross section), although it should be apparent that variations in the shape and size of shades 705 and 710 may occur without deviating from the concepts described herein. Shade 710 can be positioned between photo-cathode 205 and the wall of the vacuum chamber 235 to prevent sputtering of material from electrodes 205 and 210. Similarly, shade 705 can be positioned between the anode 210 and the corresponding area of wall of the vacuum chamber 235 for a similar purpose. In some embodiments, the shades can prevent contamination on at least some regions of the inside walls of the device, keeping pristine non-conductive regions to prevent or interrupt any conduction pathways along the inside walls of the device.

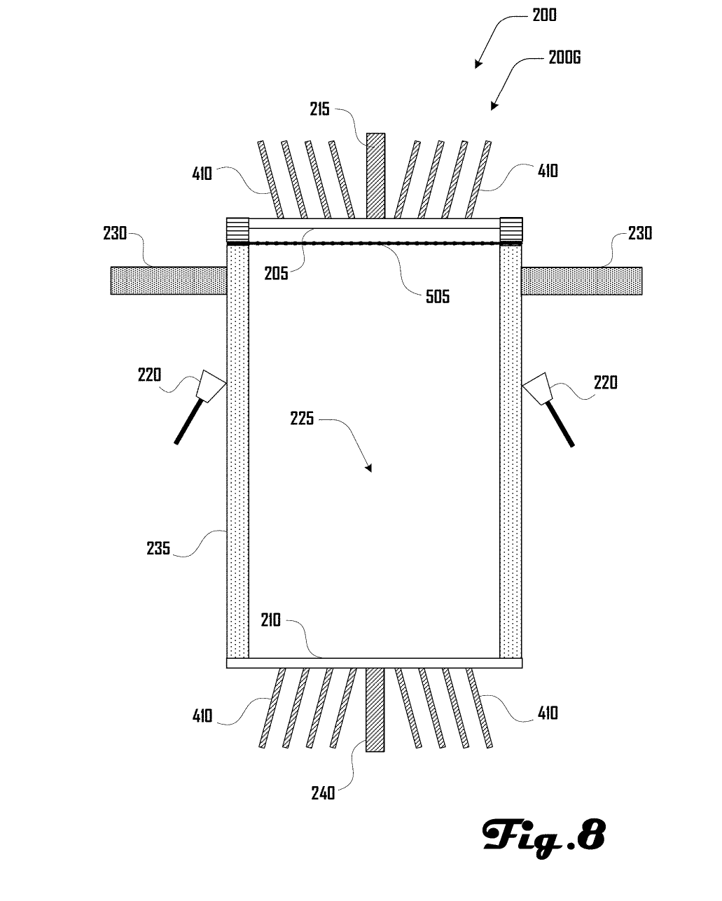

FIG. 8 illustrates an alternate embodiment 200G of a controlled photo-electric switch configured for ease of manufacture. A photo-cathode 205 can be connected to an input electrical conductor 215. An anode 210 can be connected to an output electrical conductor 240. The photo-cathode 205 can be separated from the anode 210 by a vacuum 225 contained inside a vacuum chamber 235. As with embodiment 200A of FIG. 2, photo-electric switch 200F can be connected via input electrical conductor 215 and output electrical conductor 240 to an external electrical circuit (not shown), which can apply a voltage between the photo-cathode 205 and the anode 210. An optional control grid 505 can be used to accelerate and steer the flow of electrons between the photo-cathode 205 and the anode 210.

In embodiment 200G of FIG. 8, the vacuum chamber 235 can be configured to be substantially tubular, with the photo-cathode 205 shaped and sized to cover and seal one end of the “tube” and the anode 210 shaped and sized to cover and seal the opposite end of the “tube.” A cooling architecture 410 can be attached to both the photo-cathode 205 and the anode 210 to help remove excess heat from the photo-switch 200G. In the example shown, the light sources 220 are positioned on the outside of the vacuum chamber 235, positioned such that an amount of illumination sufficient to initiate photo-emission of the photo-cathode can pass through the transparent or translucent walls of vacuum chamber 235. The tubular embodiment of the photo-electric switch 200G can be configured for ease of manufacturing. However, the embodiment shown in FIG. 8 is for illustrative purposes only and is not intended to be construed as limiting in any way.

Some example embodiments allow for the measurement of the voltage and/or the current flowing between cathode and anode. This information can be useful for ensuring the illumination provides enough electrons to ensure that sufficient current will flow while keeping a low voltage drop. Current and/or voltage sensors mounted inside the vacuum chamber 235, or alternately mounted on or near input electrical conductor 215 and/or output electrical conductor 240, can provide current and/or voltage measurements that can be used, in some embodiments, as feedback for a current control system. Ideally, embodiments of the switch 200 should balance the overall efficiency by limiting the energy involved in illumination with keeping the cathode-to-anode voltage low. In practice, this means adjusting the illumination to provide some moderate excess of electrons relative to the current needed to supply the circuit external to the device.

Some example embodiments may include modulation of the illumination to provide a maximum limit to current flow, which corresponds to the quantity of electrons provided by the photo-electric emission. This also allows setting the current to zero (switching off the photo-electric switch 200) by removing all illumination at wavelengths which can cause photo-emission of electrons. In example embodiments, when the photo-cathode 205 is not illuminated, no current will flow between the photo-cathode 205 and the anode 210 because there will be no source of electrons or ions in the vacuum.

Some example embodiments may allow for illumination, measurement, and control components to be arranged either at or in proximity to the photo-cathode 205 or at or in proximity to the anode 210, or both, which simplifies construction of devices which operate at a dangerously high voltage. In some example embodiments, controls and sensing components can be arranged at just one end of the vacuum tube to allow for easier operation or maintenance. Measurement methods include, but are not limited to, measuring current through the connections to the external circuit, sensing electrical fields inside or outside the device, and thermal, infrared, light, or ultraviolet measurements of electron impacts on the anode surface.

These devices can be constructed to be removed or inserted within active circuitry while devices around them, and the installation overall, continue to operate. This process is made easier by the inert and non-conducting nature of the device when not illuminated at an effective wavelength for photo-emission of electrons.

The described embodiments are susceptible to various modifications and alternative forms, and specific examples thereof have been shown by way of example in the drawings and are herein described in detail. It should be understood, however, that the described embodiments are not to be limited to the particular forms or methods disclosed, but to the contrary, the present disclosure is to cover all modifications, equivalents, and alternatives.

What is claimed is:

1. A power conversion circuit for the rectification of high-voltage electrical current, comprising:
a plurality of photo-electric switches that include:
a photo-cathode;
an anode;
one or more light sources; and
a vacuum chamber, the vacuum chamber enclosing at least the photo-cathode and the anode in a vacuum and holding the photo-cathode and the anode in position such that a gap exists between them; and
an electrical circuit, the electrical circuit connected to and supplying a voltage difference across the photo-cathode and the anode of each of the plurality of photo-electric switches;
wherein, for each of the plurality of photo-electric switches, the one or more light sources are positioned such that a plurality of photons emitted by the one or more light sources are absorbed by the photo-cathode, and wherein energy acquired by absorbing the plurality of photons causes a plurality of electrons to be emitted by the photo-cathode in a position for travel to the anode.

2. The power conversion circuit of claim 1, wherein the power conversion circuit converts high-voltage alternating current power to high-voltage direct current power.

3. The power conversion circuit of claim 1, wherein the power conversion circuit converts high-voltage direct current power to high-voltage alternating current power.

4. The power conversion circuit of claim 1, wherein the power conversion circuit converts one voltage of direct current power to another voltage of direct current power.

5. A high-voltage photo-electric switch, comprising:
a photo-cathode;
an anode;
one or more light sources;
a vacuum chamber, the vacuum chamber enclosing at least the photo-cathode and the anode in a vacuum and holding the photo-cathode and the anode in position such that a gap exists between them; and
an electrical circuit, the electrical circuit connected to and supplying a voltage difference across the photo-cathode and the anode;
wherein the one or more light sources are positioned such that a plurality of photons emitted by the one or more light sources are absorbed by the photo-cathode, and wherein energy acquired by absorbing the plurality of photons causes a plurality of electrons to be emitted by the photo-cathode in a position to travel to the anode.

6. The high-voltage photo-electric switch of claim 5, further comprising a control grid, wherein the control grid is positioned in proximity to the photo-cathode, wherein the control grid has a positive voltage relative to the photo-cathode, and wherein the positive voltage of the control grid helps accelerate electrons emitted by the photo-cathode away from the photo-cathode and toward the anode.

7. The high-voltage photo-electric switch of claim 5, further comprising a control ring, wherein the control ring surrounds an area inside the vacuum chamber between the photo-cathode and the anode, wherein the control ring has a negative voltage relative to the anode, and wherein the control ring helps guide electrons emitted by the photo-cathode away from an interior surface of the vacuum chamber and toward the anode.

8. The high-voltage photo-electric switch of claim 5, further comprising a cooling architecture attached to the photo-cathode.

9. The high-voltage photo-electric switch of claim 5, further comprising a cooling architecture attached to the anode.

10. The high-voltage photo-electric switch of claim 5, wherein the one or more light sources are mounted inside the vacuum chamber.

11. The high-voltage photo-electric switch of claim 5, wherein the walls of the vacuum chamber allow light to pass through them, and wherein the one or more light sources are mounted externally to the vacuum chamber.

12. The high-voltage photo-electric switch of claim 5, wherein the one or more light sources are mounted behind the photo-cathode, wherein the photo-cathode is a transmission type photo-cathode, and wherein photons from the light sources enter a back side of the photo-cathode and cause the emission of electrons from a front side of the photo-cathode.

13. The high-voltage photo-electric switch of claim 5, wherein the photo-cathode is a first photo-cathode and the anode is a second photo-cathode, and wherein the one or more light sources are positioned to provide illumination to either the first photo-cathode or the second photo-cathode, allowing the system to conduct electricity in either direction.

14. A device for the switching of electrical current comprising:
a photo-cathode;
an anode;
one or more light sources, the one or more light sources positioned such that photons emitted by the one or more light sources stimulate the emission of electrons from the photo-cathode;
an electrical circuit, the electrical circuit connected to and supplying a voltage across the photo-electric cathode and the anode; and
a vacuum chamber, the vacuum chamber enclosing at least the photo-cathode and the anode in a vacuum and holding the photo-cathode and the anode in position such that a gap exists between them.

15. The device for the switching of electrical current of claim 14, further comprising a control grid, wherein the control grid is positioned in proximity to the photo-cathode, wherein the control grid has a positive voltage relative to the photo-cathode, and wherein the positive voltage of the control grid helps accelerate electrons emitted by the photo-cathode away from the photo-cathode and toward the anode.

16. The device for the switching of electrical current of claim 14, further comprising a control ring, wherein the control ring surrounds an area inside the vacuum chamber between the photo-cathode and the anode, wherein the control ring has a negative voltage relative to the anode, and wherein the control ring helps guide electrons emitted by the photo-cathode away from an interior surface of the vacuum chamber and toward the anode.

17. The device for the switching of electrical current of claim 14, further comprising a cooling architecture attached to the device, wherein the cooling architecture helps to remove excess heat from the device.

18. The device for the switching of electrical current of claim 14, wherein the photo-cathode is a first photo-cathode and the anode is a second photo-cathode, and wherein the one or more light sources are positioned to provide illumination to either the first photo-cathode or the second photo-cathode, allowing the system to conduct electricity in either direction.

19. The device for the switching of electrical current of claim 14, further comprising a cooling architecture attached to the device.

20. The device for the switching of electrical current of claim 14, wherein at least one of the one or more light sources is capable of emitting photons at a wavelength which will not stimulate the emission of electrons from the photo-cathode, wherein the photons at a wavelength which will not stimulate the emission of electrons are used for general illumination of the device.
